(19) United States
(12) Patent Application Publication
(10) Pub. No.: US 2024/0407157 A1
(43) Pub. Date: Dec. 5, 2024

(54) SEMICONDUCTOR DEVICE

(71) Applicant: Samsung Electronics Co., Ltd., Suwon-si (KR)

(72) Inventors: Ho Kyun AN, Suwon-si (KR); Jung Min CHO, Suwon-si (KR); Gil Woon LEE, Suwon-si (KR)

(73) Assignee: Samsung Electronics Co., Ltd., Suwon-si (KR)

(21) Appl. No.: 18/425,318

(22) Filed: Jan. 29, 2024

(30) Foreign Application Priority Data
Jun. 5, 2023 (KR) 10-2023-0072103

(51) Int. Cl. H10B 12/00

(52) U.S. Cl. CPC H10B 12/50; H10B 12/02; H10B 12/315

(57) ABSTRACT

A semiconductor may include a substrate including a first active region and a second active region, an element isolation film on the substrate exposing the first active region and the second active region, a silicon germanium film on the first active region of the substrate, a first gate insulating film on the silicon germanium film and contacting the silicon germanium film, a first gate electrode on the first gate insulating film, a source/drain region in the substrate and on both sides of the first gate electrode, a second gate insulating film on the second active region of the substrate and contacting the substrate, and a second gate electrode on the second gate insulating film. A height from a lowest portion of the element isolation film to an upper face of the substrate may be different in the first active region compared to the second active region.

### CROSS-REFERENCE TO RELATED APPLICATION

This application claims priority from Korean Patent Application No. 10-2023-0072103 filed on Jun. 5, 2023 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a semiconductor device.

### 2. Description of the Related Art

As a feature size of a MOS transistor decreases, a gate length and a length of a channel formed below it also may decrease. Therefore, various research is being conducted to increase a capacitance between the gate and the channel and to improve operating features of the MOS transistor.

A silicon oxide film, which is mainly used as a gate insulating film, reaches a physical limit in electrical properties as a thickness decreases. Therefore, in order to replace the existing silicon oxide film, research on a high dielectric film having a high dielectric constant is actively being conducted. The high dielectric film may reduce a leakage current between the gate electrode and the channel region, while maintaining a thin equivalent oxide film thickness.

### SUMMARY

Aspects of the present disclosure provide a semiconductor device capable of improving performance and reliability of an element.

According to an embodiment of the present disclosure, a semiconductor device may include a substrate including a first active region and a second active region; an element isolation film on the substrate, the element isolation film exposing the first active region and the second active region; a silicon germanium film on the first active region of the substrate; a first gate insulating film on the silicon germanium film, the first gate insulating film contacting the silicon germanium film; a first gate electrode on the first gate insulating film; a source/drain region in the substrate and on both sides of the first gate electrode; a second gate insulating film on the second active region of the substrate, the second gate insulating film contacting the substrate; and a second gate electrode on the second gate insulating film. A height from a lowest portion of the element isolation film to an upper face of the substrate may be different in the first active region compared to the second active region.

According to an embodiment of the present disclosure, a semiconductor device may include a substrate including a first active region and a second active region; an element isolation film on the substrate, the element isolation film exposing the first active region and the second active region; a silicon germanium film on the first active region of the substrate; a first gate insulating film on the silicon germanium film; a first gate electrode on the first gate insulating film; a second gate insulating film on the second active region of the substrate; and a second gate electrode on the second gate insulating film. A lower face of the silicon germanium film may face the substrate and an upper face of the silicon germanium film may face the first gate insulating film. A height from a lowest portion of the element isolation film to an upper face of the silicon germanium film in the first active region may be equal to a height from a lowest portion of the element isolation film to an upper face of the substrate in the second active region.

According to an embodiment of the present disclosure, a semiconductor device may include a substrate including a first active region and a second active region; an element isolation film on the substrate, the element isolation film exposing the first active region and the second active region; a silicon germanium film on the first active region of the substrate, the silicon germanium film contacting the substrate; a first gate insulating film on the silicon germanium film; a first gate electrode on the first gate insulating film; a second gate insulating film on the second active region of the substrate; and a second gate electrode on the second gate insulating film. A lower face of the silicon germanium film may face the substrate and an upper face of the silicon germanium film may face the first gate insulating film. A first height in the first active region may be from a level of an upper face of the element isolation film to a level of the upper face of the silicon germanium film. A second height in the second active region may be from the level of the upper face of the element isolation film to a level of the upper face of the substrate. The first height may be equal to the second height.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram for explaining a semiconductor device according to some embodiments.

FIG. 2 is an enlarged view of a portion P of FIG. 1.

FIG. 3 is an enlarged view of a portion Q of FIG. 1.

FIGS. 4a and 4b are diagrams that schematically show concentration of germanium (Ge) along a SCAN LINE of FIG. 2, respectively.

FIG. 5 is a schematic layout diagram of a semiconductor device according to some embodiments.

FIG. 6 is a schematic enlarged layout diagram showing a portion R3 of FIG. 6.

FIG. 7 is a cross-sectional view taken along line A-A of FIG. 6.

FIG. 8 is a cross-sectional view taken along line B-B of FIG. 6.

FIG. 9 is a layout diagram for explaining a semiconductor device according to some embodiments.

FIG. 10 is a perspective view for explaining the semiconductor device according to some embodiments.

FIG. 11 is a cross-sectional view taken along C-C and D-D of FIG. 9.

FIG. 12 is a layout diagram for explaining a semiconductor device according to some embodiments.

FIG. 13 is a perspective view for explaining the semiconductor device according to some embodiments.

FIG. 14 is a diagram for explaining a semiconductor device according to some embodiments.

FIGS. 15 to 20 are intermediate operation diagrams for explaining a method of fabricating a semiconductor device according to some embodiments.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

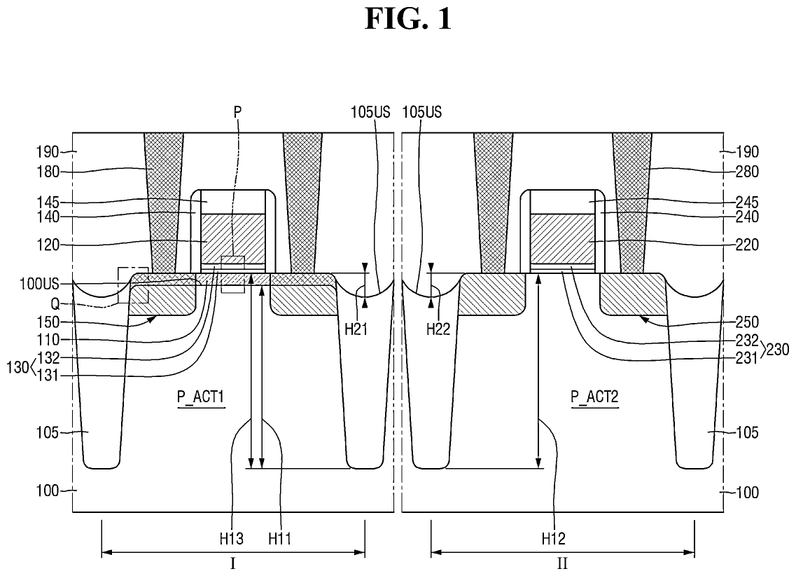

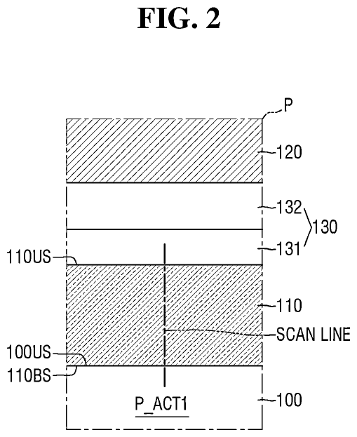

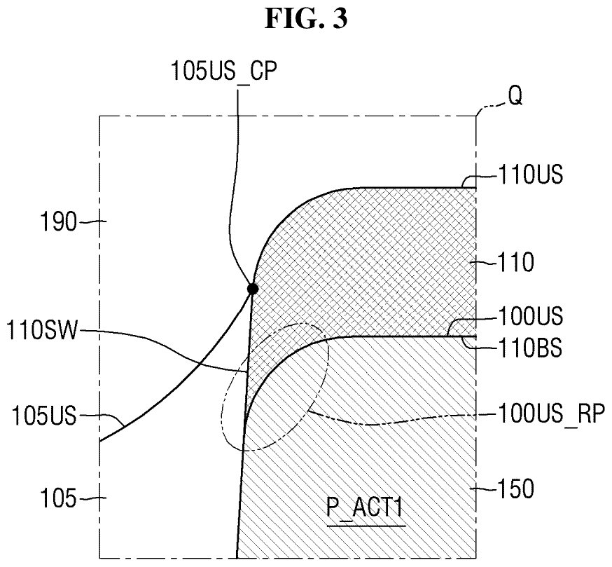

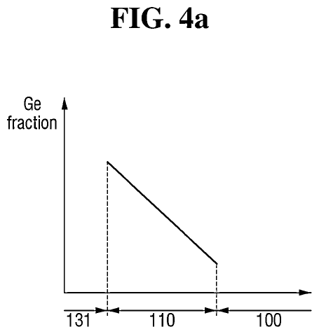

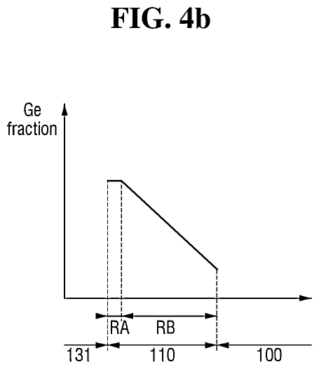

FIG. 1 is a diagram for explaining a semiconductor device according to some embodiments. FIG. 2 is an enlarged view of a portion P of FIG. 1. FIG. 3 is an enlarged view of a portion Q of FIG. 1. FIGS. 4a and 4b are diagrams that schematically show concentration of germanium (Ge) along a SCAN LINE of FIG. 2, respectively.

Referring to FIGS. 1 to 4b, the semiconductor device according to some embodiments may include a substrate 100, a first element isolation film 105, a silicon germanium film 110, a first gate electrode 120, a first gate insulating film 130, a first source/drain region 150, a second gate electrode 220, a second gate insulating film 230, and a second source/drain region 250.

The substrate 100 may include a first region I and a second region II. The first region I and the second region II may be regions spaced apart from each other or regions connected to each other.

The substrate 100 may be a silicon substrate or silicon-on-insulator (SOI). In contrast, the substrate 100 may include, but is not limited to, silicon germanium, silicon germanium on insulator (SGOI), indium antimonide, lead telluride, indium arsenide, indium phosphide, gallium arsenide or gallium antimonide.

In some embodiments, the substrate 100 may be a silicon substrate. Alternatively, the substrate 100 may be in the form of bonding a silicon substrate and a base substrate made of another material. The base substrate may be, but is not limited to, a substrate made of the compound semiconductor described above. If the substrate 100 is in the form of bonding the silicon substrate and the base substrate, a silicon germanium film 110, which will be described later, may be formed on the silicon substrate.

The silicon germanium film 110, the first gate electrode 120, the first gate insulating film 130 and the first source/drain region 150 may be disposed in a first region I of the substrate 100. The second gate electrode 220, the second gate insulating film 230 and the second source/drain region 250 may be disposed in a second region II of the substrate 100.

A first element isolation film 105 may be disposed in the substrate 100. In other words, the first element isolation film 105 may be disposed on the substrate 100. The substrate 100 may include an active region defined by first element isolation films 105. For example, the first element isolation film 105 may define a first peri-active region P_ACT1 and a second peri-active region P_ACT2. The first peri-active region P_ACT1 and the second peri-active region P_ACT2 can be exposed by the first element isolation film 105 on the substrate.

The first peri-active region P_ACT1 included in the first region I may be, for example, a region in which a PMOS region is formed. The second peri-active region P_ACT2 included in the second region II may include an NMOS region.

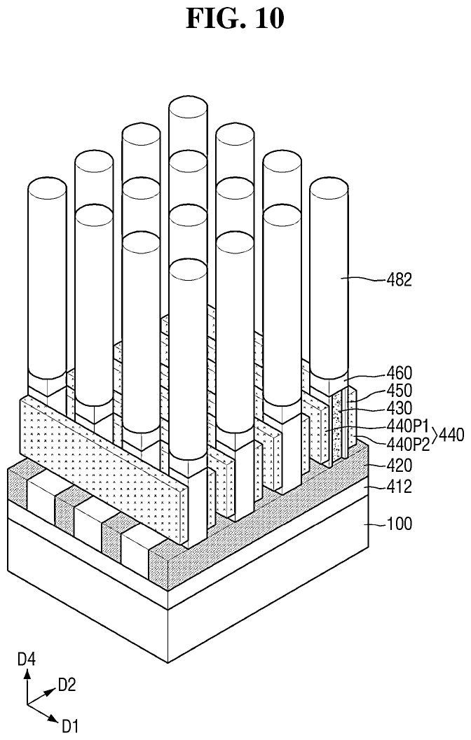

The first element isolation film 105 may be formed as a shallow trench isolation (STI) structure. The first element isolation film 105 may extend in a thickness direction (e.g., D4 of FIG. 10) of the substrate 100.

The first element isolation film 105 may include, for example, at least one of silicon oxide, silicon nitride, silicon oxynitride, and combinations thereof. Although the first element isolation film 105 is shown as a single film, this is only for convenience of explanation and is not limited thereto.

Although an upper face 105 of the first element isolation film is shown to have a concave shape, the embodiment is not limited thereto. Unlike the shown example, as an example, the upper face 105US of the first element isolation film may have a convex shape. As another example, the upper face 105US of the first element isolation film may include a portion having a convex shape, and a portion having a concave shape.

In the first peri-active region P_ACT1, the upper face 100US of the substrate may have a convex shape. In the second peri-active region P_ACT2, the upper face 100US of the substrate may have a convex shape. In FIG. 3, in the first peri-active region P_ACT1 and the second peri-active region P_ACT2, the upper face 100US of the substrate may include a flat portion and a convex portion 100US_RP. The convex portion 100US_RP of the upper face 100US of the substrate may be located at a boundary between the substrate 100 and the first clement isolation film 105. That is, at the boundary between the substrate 100 and the first element isolation film 105, the upper face 100US of the substrate may be convex.

A silicon germanium film 110 may be disposed on the first peri-active region P_ACT1. The silicon germanium film 110 may be disposed on the upper face 100US of the substrate. The silicon germanium film 110 is in contact with the substrate 100.

The silicon germanium film 110 may extend along the upper face 100US of the substrate. The silicon germanium film 110 may be conformally formed on the substrate 100. For example, the silicon germanium film 110 may be conformally formed in the planar portion of the upper face 100US of the substrate.

In the semiconductor device according to some embodiments, the expression “the film is formed conformally” may mean that a film of uniform thickness is formed. The silicon germanium film 110 may be disposed on the substrate 100 with a uniform thickness. For example, in the silicon germanium film 110 extending along the upper face 100US of the substrate, a ratio of a minimum value of a thickness of the silicon germanium film 110 to a maximum value of the thickness of the silicon germanium film 110 may be 90% or more.

The silicon germanium film 110 may include an upper face 110US and a lower face 110BS. The lower face 110BS of the silicon germanium film may face the substrate 100. The upper face 110US of the silicon germanium film may face the first gate insulating film 130, which will be described below. The lower face 110BS of the silicon germanium film may be in contact with the upper face 100US of the substrate.

Since the silicon germanium film 110 extends along the upper face 100US of the substrate, the silicon germanium film 110 may be formed along the shape of the upper face 100US of the substrate. Since the upper face 100US of the substrate has a convex shape, the lower face 110BS of the silicon germanium film may have a concave shape. The upper face 110US of the silicon germanium film may have a convex shape like the upper face 100US of the substrate.

In FIG. 3, the first element isolation film 105 may be in contact with the silicon germanium film 110. The upper face 105US of the first element isolation film may include a contact point 105 US_CP that is in contact with the silicon germanium film 110. For example, the upper face 110US of the silicon germanium film may start from the contact point 105US_CP of the first element isolation film.

The silicon germanium film 110 may include side walls 110SW that connect the lower face 110BS of the silicon germanium film and the upper face 110US of the silicon germanium film. The side walls 110SW of the silicon germanium film may extend along the first element isolation film 105. The first element isolation film 105 may cover the side walls 110SW of the silicon germanium film.

At least a part of the lower face 110BS of the silicon germanium film may be located below the contact point 105US_CP of the first element isolation film on the basis of the lowest portion of the first element isolation film 105. The entire upper face 110US of the silicon germanium film may be located above the contact point 105US_CP of the first element isolation film. Although FIGS. 1 and 3 show that the entire lower face 110BS of the silicon germanium film is shown as being located below the contact point 105US_CP of the first element isolation film, this is only for convenience of explanation, and the embodiment is not limited thereto.

The silicon germanium film 110 may be formed of silicon germanium. For example, the silicon germanium film 110 may include a single crystal silicon germanium film.

As an example, the silicon germanium film 110 may include doped p-type impurities and/or n-type impurities. As another example, the silicon germanium film 110 may be formed of an undoped silicon germanium film. Here, the term “undoped” does not mean that impurities are not contained, but means that intentionally doped impurities are not contained. That is, the undoped silicon germanium film may or may not contain impurities.

A first height H11 from the lowest portion of the first element isolation film 105 to the upper face 100US of the substrate in the first peri-active region P_ACT1 differs from a second height H12 from the lowest portion of the first element isolation film 105 to the upper face 100US of the substrate in the second peri-active region P_ACT2. For example, the first height H11 from the lowest portion of the first element isolation film 105 to the upper face 100US of the substrate in the first peri-active region P_ACT1 is smaller than the second height H12 from the lowest portion of the first element isolation film 105 to the upper face 100US of the substrate in the second peri-active region P_ACT2. The first height H11 and the second height H12 may be measured at a portion in which the gate electrodes 120 and 220 overlap the substrate 100 in the thickness direction of the substrate 100.

A third height H13 from the lowest portion of the first element isolation film 105 to the upper face 110US of the silicon germanium film in the first peri-active region P_ACT1 may be the same as the second height H12 from the lowest portion of the first element isolation film 105 to the upper face 100US of the substrate in the second peri-active region P_ACT2. Here, the “same height” means not only a case where the heights at the two positions to be compared are completely the same, but also includes a minute height difference that may occur due to process margins or measurement errors. The third height H13 may be measured at a portion where the first gate electrode 120 overlaps the silicon germanium film 110 in the thickness direction of the substrate 100.

A fourth height H21 from the upper face 105US of the first element isolation film to the upper face 110US of the silicon germanium film in the first peri-active region P_ACT1 may be the same as a fifth height H22 from the upper face 105US of the first element isolation film to the upper face 100US of the substrate in the second peri-active region P_ACT2. For example, the fourth height H14 and the fifth height H15 may be measured at the lowest portion of the upper face 105US of the first clement isolation film.

The first gate insulating film 130 may be disposed on the silicon germanium film 110. The first gate insulating film 130 may be in contact with the silicon germanium film 110. For example, the first gate insulating film 130 may be in contact with the upper face 110US of the silicon germanium film.

The first gate insulating film 130 includes a first interfacial film 131 and a first high dielectric constant insulating film 132 that are sequentially disposed on the silicon germanium film 110. The first interfacial film 131 may be disposed between the silicon germanium film 110 and the first high dielectric constant insulating film 132.

A second gate insulating film 230 may be disposed on the substrate 100. The second gate insulating film 230 may be in contact with the substrate 100. For example, the second gate insulating film 230 may be in contact with the upper face 100US of the substrate.

The first gate insulating film 130 includes a first interfacial film 131 and a first high dielectric constant insulating film 132 that are sequentially disposed on the silicon germanium film 110. The first interfacial film 131 may be disposed between the silicon germanium film 110 and the first high dielectric constant insulating film 132.

The second gate insulating film 230 may include a second interfacial film 231 and a second high dielectric constant insulating film 232 that are sequentially disposed on the substrate 100. The second interfacial film 231 may be disposed between the substrate 100 and the second high dielectric constant insulating film 232.

The first interfacial film 131 may be in contact with the silicon germanium film 110. For example, the first interfacial film 131 may be in direct contact with the upper face 110US of the silicon germanium film. The second interfacial film 231 may be in contact with the substrate 100. For example, the second interfacial film 231 may be in direct contact with the upper face 100US of the substrate. The first interfacial film 131 and the second interfacial film 231 may include, for example, silicon oxide films.

The first high dielectric constant insulating film 132 and the second high dielectric constant insulating film 232 may include, for example, a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

In FIGS. 4a and 4b, the germanium fraction of the silicon germanium film 110 may change, as it goes away from the first gate insulating film 130. For example, the germanium fraction of the silicon germanium film 110 may decrease, as it goes away from the first gate insulating film 130.

Although the germanium fraction in the first interfacial film 131 and the germanium fraction in the substrate 100 are shown to be zero, they are only for convenience of explanation, and the embodiment is not limited thereto. That is, the first interfacial film 131 and/or the substrate 100 may include germanium diffused from the silicon germanium film 110.

As an example, at the interface between silicon germanium film 110 and substrate 100, the germanium fraction of the silicon germanium film 110 is greater than zero. As another example, unlike the shown example, the germanium fraction of the silicon germanium film 110 may be zero at the interface between the silicon germanium film 110 and the substrate 100.

In FIG. 4a, the germanium fraction of the silicon germanium film 110 may continuously decrease, as it goes away from the first interfacial film 131. Although the germanium fraction of the silicon germanium film 110 is shown to decrease linearly, this is only for convenience of explanation, and the embodiment is not limited thereto.

In FIG. 4b, the silicon germanium film 110 may include a first portion RA and a second portion RB. The germanium fraction may be constant inside the first portion RA of the silicon germanium film 110. The germanium fraction may continuously decrease inside the second portion RB of the silicon germanium film 110. The first portion RA of the silicon germanium film 110 may be closer to the first interfacial film 131 than the second portion RB of the silicon germanium film 110. For example, the first interfacial film 131 may be formed by oxidizing the silicon germanium film 110. At this time, a germanium condensation may occur in the silicon germanium film 110 that borders the first interfacial film 131 during the formation of the first interfacial film 131. Therefore, the germanium fraction may be constant inside the first portion RA of the silicon germanium film 110.

A semiconductor device according to some embodiments may include an NC (Negative Capacitance) FET that uses a negative capacitor. For example, referring to FIGS. 1-3, the first high dielectric constant insulating film 132 and the second high dielectric constant insulating film 232 may include a ferroelectric material film having ferroelectric properties, and a paraclectric material film having paraelectric properties.

The ferroelectric material film may have a negative capacitance, and the paraclectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value. When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, silicon oxide and metal oxide having a high dielectric constant. The metal oxide included in the paraelectric material film may include, for example, at least one of hafnium oxide, zirconium oxide, and aluminum oxide, but is not limited thereto.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, 0.5 to 10 nm, but is not limited thereto. Since a critical thickness that exhibits the ferroelectric properties may vary for each ferroelectric material, the thickness of the ferroelectric material film may vary depending on the ferroelectric material.

As an example, each of the first gate insulating film 130 and the second gate insulating film 230 may include one ferroelectric material film. As another example, each of the first gate insulating film 130 and the second gate insulating film 230 may include a plurality of ferroelectric material films spaced apart from each other. Each of the first gate insulating film 130 and the second gate insulating film 230 may have a stacked film structure in which the plurality of ferroelectric material films and the plurality of paraclectric material films are alternately stacked.

A first gate electrode 120 may be disposed on the first gate insulating film 130. A second gate electrode 220 may be disposed on the second gate insulating film 230.

Although one first gate electrode 120 and one second gate electrode 220 are shown as being disposed between adjacent first element isolation films 105, this is only for convenience of explanation, and the embodiment is not limited thereto.

The first gate electrode 120 and the second gate electrode 220 may include at least one of metal, conductive metal nitride, conductive metal carbonitride, conductive metal carbide, metal silicide, doped semiconductor material, conductive metal oxide, and conductive metal oxynitride. The first gate electrode 120 and the second gate electrode 220 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), impurity-doped silicon, impurity-doped silicon germanium, impurity-doped germanium, and combinations thereof, but is not limited thereto. The conductive metal oxide and conductive metal oxynitride may include, oxidized forms of the aforementioned materials, but is not limited thereto.

Although each of the first gate electrode 120 and the second gate electrode 220 are shown as single films, this is only for convenience of explanation, and the embodiment is not limited thereto.

A first gate mask pattern 145 may be disposed on the first gate electrode 120. A second gate mask pattern 245 may be disposed on the second gate electrode 220. The first gate mask pattern 145 and the second gate mask pattern 245 may include an insulating material, and may include, for example, silicon oxide, silicon oxynitride, or silicon nitride, and the like, but is not limited thereto.

A first gate spacer 140 may be disposed on side walls of the first gate electrode 120. A first gate mask pattern 145 may be disposed between the first gate spacers 140. A second gate spacer 240 may be disposed on side walls of the second gate electrode 220. A second gate mask pattern 245 may be disposed between the second gate spacers 240.

The first gate spacer 140 and the second gate spacer 240 may include an insulating material, and may include, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), and silicon oxycarbide (SiOC). Although the first gate spacer 140 and the second gate spacer 240 are shown as being a single film, this is only for convenience of explanation, and the embodiment is not limited thereto.

The first source/drain region 150 may be disposed on both sides of the first gate electrode 120. The first source/drain region 150 may be formed in the substrate 100.

The first source/drain region 150 may be formed inside a silicon germanium film 110 disposed on the upper face 100US of the substrate. For example, a part of the first source/drain region 150 may be disposed inside the silicon germanium film 110.

The first source/drain region 150 may include p-type impurities. For example, p-type impurities may include at least one of boron (B) and gallium (Ga).

A second source/drain region 250 may be disposed on both sides of the second gate electrode 220. The second source/drain region 250 may be formed inside the substrate 100.

The second source/drain regions 250 may include n-type impurities. For example, the n-type impurities may include at least one of phosphorus (P), arsenic (As), antimony (Sb) and bismuth (Bi).

The interlayer insulating film 190 is disposed on the substrate 100. The interlayer insulating film 190 covers the first source/drain region 150, the second source/drain region 250, the first gate mask pattern 145 and the second gate mask pattern 245.

The interlayer insulating film 190 may include, for example, at least one of silicon oxide, silicon nitride, and silicon oxynitride.

A first contact 180 penetrates through the interlayer insulating film 190 and may be connected to the first source/drain region 150. The upper face of the first contact 180 may be higher than the upper face of the first gate mask pattern 145.

A second contact 280 penetrates through the interlayer insulating film 190 and may be connected to the second source/drain region 250. An upper face of the second contact 280 may be higher than the upper face of the second gate mask pattern 245.

The first contact 180 and second contact 280 may include, for example, a conductive material. The first contact 180 and the second contact 280 may include, for example, at least one of metal, conductive metal nitride, conductive metal carbonitride, conductive metal carbide, metal silicide, doped semiconductor material, conductive metal oxide, conductive metal oxynitride, and a two-dimensional material (2D material). Although the first contact 180 and the second contact 280 are shown as being a single film, this is only for convenience of explanation, and the embodiment is not limited thereto.

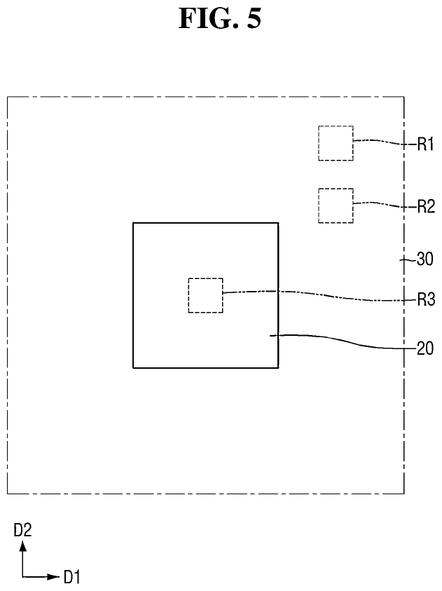

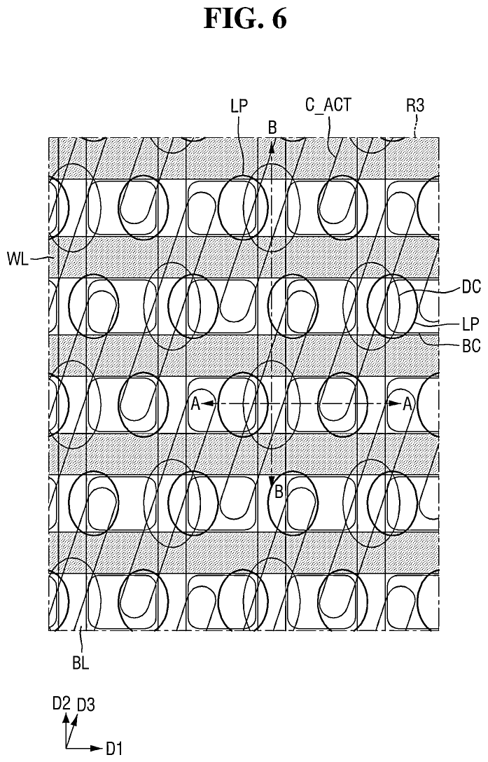

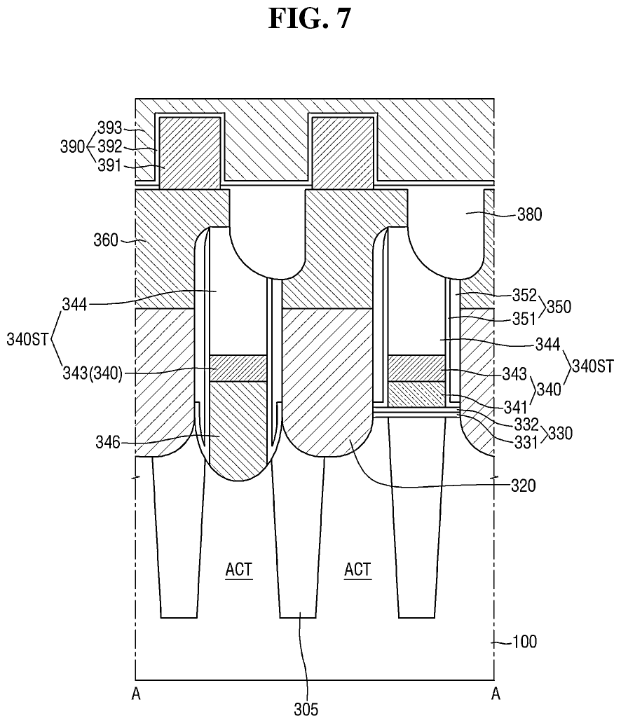

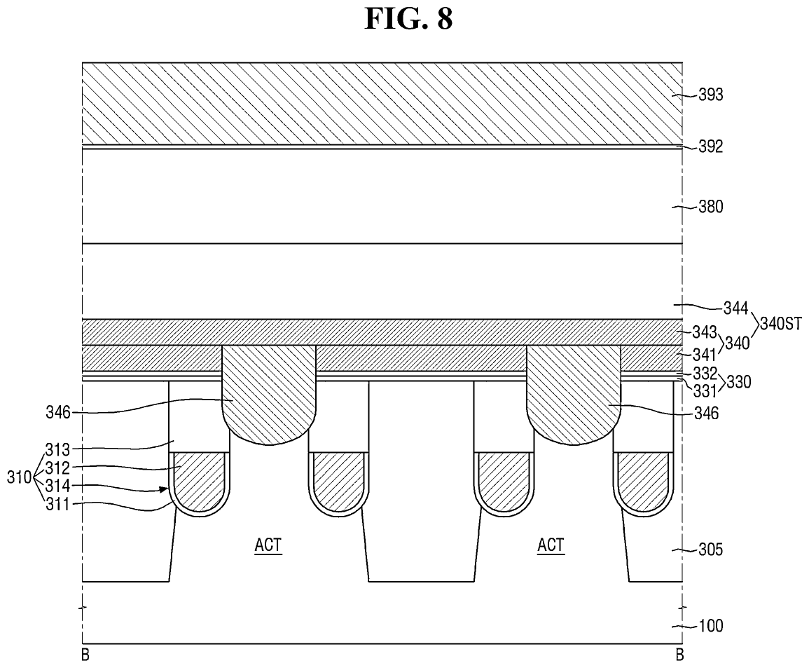

FIG. 5 is a schematic layout diagram of a semiconductor device according to some embodiments. FIG. 6 is a schematic enlarged layout diagram showing a portion R3 of FIG. 6. FIG. 7 is a cross-sectional view taken along line A-A of FIG. 6. FIG. 8 is a cross-sectional view taken along line B-B of FIG. 6.

For reference, although the diagrams relating to the semiconductor device according to some embodiments show a dynamic random access memory (DRAM), the embodiment is not limited thereto. Also, FIG. 6 shows a layout diagram except the first capacitor 190.

Referring to FIG. 5, a semiconductor device according to some embodiments may include a cell region 20, and a peri-region 30 defined around the cell region 20.

In other words, the substrate (100 of FIG. 1) may include a memory cell region 20 and a peri-region 30. For example, the memory cell region 20 may be a region in which memory cells are disposed. The peri-region 30 may be a region in which circuits for operating the memory cells of the memory cell region 20 are disposed.

A cross-sectional view obtained by cutting the portion R1 of FIG. 5 in a first direction D1 or a second direction D2 may be a first cross-sectional view. A cross-sectional view obtained by cutting the portion R2 of FIG. 5 in the first direction D1 or the second direction D2 may be a second cross-sectional view. The first direction D1 may intersect the second direction D2.

As an example, the first cross-sectional view may be a diagram shown in the first region I of FIG. 1. The second cross-sectional view may be a diagram shown in the second region II of FIG. 1. That is, the first peri-active region P_ACT1 may be located at the portion R1 of FIG. 5, and the second peri-active region P_ACT2 may be located at the portion R2 of FIG. 5.

In other words, the semiconductor device described using FIGS. 1 to 4b may be disposed in the peri-region 30 of FIG. 5.

Descriptions of the portion R1 of FIG. 5 and the portion R2 of FIG. 7 are similar to description using FIGS. 1 to 4b, the following description will focus on the portion R3 of FIG. 5.

Referring to FIG. 6, a semiconductor device according to some embodiments may include a plurality of first cell active regions C_ACT. The first cell active region C_ACT may be defined by a second clement isolation film (305 of FIG. 7) formed in the substrate (100 of FIG. 7).

As the design rule of the semiconductor device decreases, the first cell second active region ACT may be disposed in the form of a bar of a diagonal line or an oblique line, as shown. The first cell active region C_ACT may have a bar shape extending in the third direction D3.

A plurality of gate electrodes may be disposed on the first cell active region C_ACT in the first direction D1 across the first cell active region C_ACT. The plurality of gate electrodes may extend to be parallel to each other. The plurality of gate electrodes may be, for example, a plurality of word lines WL.

The word lines WL may be disposed at regular intervals. A width of the word lines WL or an interval of the word lines WL may be determined according to design rules.

A plurality of bit lines BL extending in a second direction D2 orthogonal to the word lines WL may be disposed on the word lines WL. A plurality of bit lines BL may extend in the second direction D2 across the first cell active region C_ACT.

The plurality of bit lines BL may extend to be parallel to each other. The bit lines BL may be disposed at regular intervals. The width of the bit lines BL or the interval between the lines BL may be determined according to design rules.

A semiconductor device according to some embodiments may include various contact arrangements formed on the first cell active region C_ACT. Various contact arrangements may include, for example, a direct contact DC, a buried contact BC, a landing pad LP, and the like.

Here, the direct contact DC may mean a contact that electrically connects the first cell active region C_ACT to the bit line BL. The buried contact BC may mean a contact that connects the first cell active region C_ACT to a first lower electrode (391 of FIG. 7) of the first capacitor (390 of FIG. 7).

Due to the placement structure, a contact area between the buried contact BC and the first cell active region C_ACT may be small. Therefore, a conductive landing pad LP may be introduced to enlarge the contact area with the first cell active region C_ACT and enlarge the contact area with the first lower electrode (391 of FIG. 7) of the first capacitor.

The landing pad LP may be disposed between the first cell active region C_ACT and the buried contact BC, and may be disposed between the buried contact BC and the first lower electrode (391 of FIG. 7) of the first capacitor. In the semiconductor device according to some embodiments, the landing pad LP may be disposed between the buried contact BC and the first lower electrode (391 of FIG. 7) of the first capacitor. By enlarging the contact area through the introduction of the landing pad LP, the contact resistance between the first cell active region C_ACT and the first lower electrode (391 of FIG. 7) may decrease.

In the semiconductor device according to some embodiments, the direct contact DC may be disposed at a central portion of the first cell active region C_ACT. The buried contact may be disposed at both distal end portions of the first cell active region C_ACT. As the buried contact are disposed at both distal end portions of the first cell active region C_ACT, the landing pads LP may be disposed to be partially overlap the buried contact BC to be adjacent to both distal ends of the first cell active region C_ACT. In other words, the buried contact BC may be formed to overlap the first cell active region C_ACT and the second element isolation film (305 of FIG. 7) disposed between the adjacent word lines WL and between the adjacent bit lines BL.

A word line WL may be formed in a structure buried in the substrate 100. The word line WL may be disposed across the first cell active region C_ACT between the direct contact DC and the buried contact BC.

As shown, two word lines WL may be disposed to cross one first cell active region C_ACT. Since the first cell active region C_ACT is disposed in the form of a diagonal line, the word line WL may have an angle of less than 90 degrees with the first cell active regions C_ACT.

The direct contact DC and the buried contact BC may be disposed symmetrically. Therefore, the direct contact DC and the buried contact BC may be disposed on a straight line along the first direction D1 and the second direction D2.

On the other hand, unlike the direct contact DC and the buried contact BC, the landing pad LP may be disposed in a zigzag pattern in the second direction D2 in which the bit line BL extends. Also, the landing pad LP may be disposed to overlap the same side portions of the bit lines BL in the first direction D1 in which the word line WL extends.

For example, each of the landing pads LP of the first line overlaps the left side of the corresponding bit line BL, and each of the landing pads LP of the second line may overlap the right side of the corresponding bit line BL

Referring to FIGS. 6 to 8, a semiconductor device according to some embodiments may include a second element isolation film 305, a plurality of gate structures 310, a plurality of bit line structures 340ST, a bit line contact 346, a storage contact 320, and a first capacitor 190.

The first cell active region C_ACT defined by the second element isolation film 305 may have a long island shape including a short axis and a long axis, as shown in FIG. 6. The first cell active region C_ACT may have a diagonal line shape to have an angle of less than 90 degrees with respect to the word lines WL formed in the second element isolation film 305. Also, the first cell active region C_ACT may have a diagonal line shape to have an angle of less than 90 degrees with respect to the bit line BL formed on the second element isolation film 305.

A gate structure 310 may be formed in the substrate 100 and the second element isolation film 305. The gate structure 310 may be formed across the second element isolation film 305 and the first cell active region C_ACT defined by the second element isolation film 305. That is, one gate structure 310 may be formed in the substrate 100 and the second clement isolation film 305 located in the first direction DI in which the gate structure 310 extends.

The gate structure 310 may include a gate trench 314, a third gate insulating film 311, a third gate electrode 312, and a gate capping pattern 313 that are formed in the substrate 100 and the second element isolation film 305. Here, the third gate electrode 312 may correspond to the word line WL.

The third gate insulating film 311 may extend along side walls and a bottom face of the gate trench 314. The third gate insulating film 311 may include at least one of silicon oxide, silicon nitride, silicon oxynitride or a high dielectric constant material having a higher dielectric constant than silicon oxide. The high dielectric constant material may be the same as the description regarding the first high dielectric constant insulating film 132 and the second high dielectric constant insulating film 232 of FIG. 1.

A third gate electrode 312 may be disposed on the third gate insulating film 311. The third gate electrode 312 may partially fill the gate trench 314. The third gate electrode 312 may include at least one of metal, conductive metal nitride, conductive metal carbonitride, conductive metal carbide, metal silicide, doped semiconductor material, conductive metal oxynitride, and conductive metal oxide. The third gate electrode 312 may be made of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or a combination thereof, but is not limited thereto.

Although it is not shown, an impurity doping region may be formed on at least one side of the gate structure 310. The impurity doping region may be a source/drain region of a transistor.

A gate capping pattern 313 may be disposed on the third gate electrode 312. The gate capping pattern 313 may fill the remaining gate trench 314 in which the third gate electrode 312 is formed. The gate capping pattern 313 includes an insulating material.

A bit line structure 340ST may include a cell conductive line 340 and a cell line capping film 344. The cell conductive line 340 may be disposed on the substrate 100 and the second element isolation film 305 on which the gate structure 310 is disposed. The cell conductive line 340 may intersect the second element isolation film 305 and the first cell active region C_ACT defined by the second clement isolation film 305. One cell conductive line 340 may be disposed on the substrate 100 and the second element isolation film 305 located in the second direction D2 in which the cell conductive line 340 extends. The cell conductive line 340 may be formed to intersect the gate structure 310. Here, the cell conductive line 340 may correspond to the bit line BL.

The cell conductive lines 340 may include a lower cell conductive line 341, and an upper cell conductive line 343 on the lower cell conductive line 341. In the semiconductor device according to some embodiments, the cell conductive line 340 may have the same stack structure as a part of the first gate electrode 120.

In other words, when the conductive material included in the cell conductive line 340 of the cell region (20 of FIG. 5) is formed, a part of the conductive material included in the first gate electrode 120 in the peri-region (30 of FIG. 5) may be formed.

A bit line contact 346 may be disposed between the cell conductive line 340 and the substrate 100. That is, the cell conductive line 340 may be formed on the bit line contact 346. For example, the bit line contact 346 may be located at a point where the cell conductive line 340 intersects the central portion of the first cell active region C_ACT having a long island shape. The bit line contact 346 may be formed between the substrate 100 and the cell conductive line 340 in the central portion of the first cell active region C_ACT. The bit line contact 346 may electrically connect the cell conductive line 340 and the substrate 100. The bit line structure 340ST may be connected to the first cell active region C_ACT through the bit line contact 346. The bit line contact 346 may correspond to the direct contact DC. The bit line contact 346 may include, for example, at least one of impurity-doped semiconductor material, conductive silicide compound, conductive metal nitride, conductive metal oxide, and a metal.

A cell line capping film 344 may be disposed on the cell conductive lines 340. The cell line capping film 344 includes an insulating material.

The cell insulating film 330 may be disposed on the substrate 100 and the second element isolation film 305. The cell insulating film 330 may be formed on the substrate 100 and the second element isolation film 305 in which the bit line contact 346 is not formed. The cell insulating film 330 may be formed between the substrate 100 and the cell conductive line 340, and between the second element isolation film 305 and the cell conductive line 340. Although the cell insulating film 330 may be a single film, the cell insulating film 330 may be a multi-film including a first cell insulating film 331 and a second cell insulating film 332 as shown. For example, the first cell insulating film 331 may include an oxide film, and the second cell insulating film 332 may include a nitride film, but the disclosure is not limited thereto.

A cell line spacer 350 may be disposed on side walls of the cell conductive line 340 and the cell line capping film 344. Although the cell line spacer 350 may be a single film, as shown, the cell line spacer 350 may be a multi-film including a first cell line spacer 351 and a second cell line spacer 352. For example, the first and second cell line spacers 351 and 352 may include, but is not limited to, one of a silicon oxide film, a silicon nitride film, silicon oxynitride film (SiON), silicon oxycarbonitride film (SiOCN), air, and combinations thereof.

The storage contact 320 may be disposed between adjacent cell conductive lines 340. The storage contact 320 may overlap the substrate 100 and the second element isolation film 305 between adjacent cell conductive lines 340. Here, the storage contact 120 may correspond to the buried contact BC. The storage contact 320 may include, for example, at least one of an impurity-doped semiconductor material, a conductive silicide compound, a conductive metal nitride, a conductive metal oxide, and a metal.

A storage pad 360 may be disposed on the storage contact 320. The storage pad 360 may be electrically connected to the storage contact 320. Here, the storage pad 360 may correspond to the landing pad LP. The storage pad 360 may include, for example, at least one of impurity-doped semiconductor material, conductive silicide compound, conductive metal nitride, conductive metal oxide, and metal.

A pad isolation insulating film 380 may be disposed on the storage pad 360 and the bit line structure 340ST. For example, the pad isolation insulating film 380 may be disposed on the cell line capping film 344. The pad isolation insulating film 380 may define a region of the storage pads 360 that form a plurality of isolation regions. Also, the pad isolation insulating film 380 may be patterned to expose at least a part of the upper face of the storage pad 360. The pad isolation insulating film 380 includes an insulating material.

A first capacitor 390 may be disposed in the pad isolation insulating film 380. The first capacitor 390 may be electrically connected to the storage contact 320 through the storage pad 360. The first capacitor 390 includes a first lower electrode 391, a first capacitor dielectric film 392, and a first upper electrode 393.

The first lower electrode 391 may be disposed on the storage pad 360. Although the first lower electrode 391 is shown to have a pillar shape, the embodiment is not limited thereto. Of course, the first lower electrode 391 may have a cylindrical shape. The first capacitor dielectric film 392 is disposed on the first lower electrode 391. The first capacitor dielectric film 392 may be formed along the profile of the first lower electrode 391. The first upper electrode 393 is disposed on the first capacitor dielectric film 392. The first upper electrode 393 may wrap an outer side wall of the first lower electrode 391.

The first lower electrode 391 and the first upper electrode 393 may each include, for example, a doped semiconductor material, conductive metal nitride (e.g., titanium nitride, tantalum nitride, niobium nitride or tungsten nitride, etc.), a metal (e.g., ruthenium, iridium, titanium, tantalum, etc.), and conductive metal oxide (e.g., iridium oxide or niobium oxide, etc.), but is not limited thereto.

The first capacitor dielectric film 392 may include, for example, one of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof, but is not limited thereto.

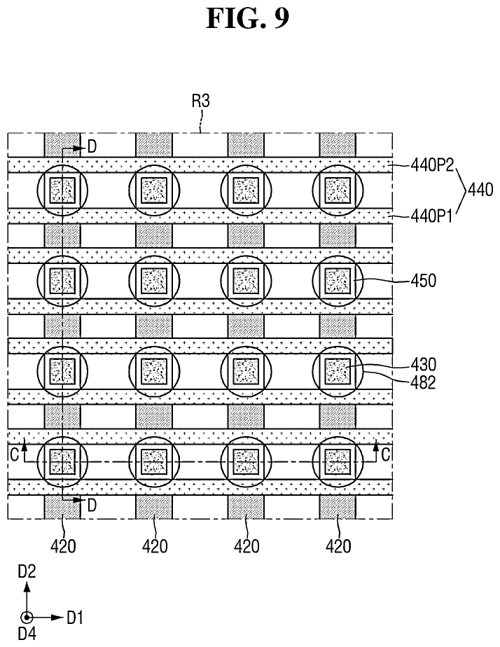

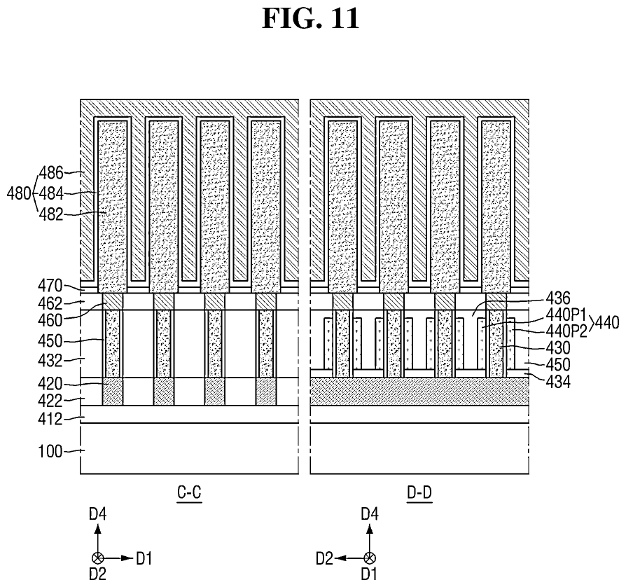

FIG. 9 is a layout diagram for explaining a semiconductor device according to some embodiments. FIG. 10 is a perspective view for explaining the semiconductor device according to some embodiments. FIG. 11 is a cross-sectional view taken along C-C and D-D of FIG. 9. For reference, FIG. 9 may be an enlarged view of a portion R3 of FIG. 5.

Referring to FIGS. 9 to 11, the semiconductor device according to some embodiments may include a substrate 100, a plurality of first conductive lines 420, a channel layer 430, a fourth gate electrode 440, a fourth gate insulating film 450, and a second capacitor 480. The semiconductor device according to some embodiments may be a memory device that includes a vertical channel transistor (VCT). The vertical channel transistor may refer to a structure in which the channel length of the channel layer 430 extends from the substrate 100 along the vertical direction.

A lower insulating layer 412 may be disposed on the substrate 100. A plurality of first conductive lines 420 may be spaced apart from each other in the first direction D1 and extend in the second direction D2 on the lower insulating layer 412. A plurality of first insulating patterns 422 may be disposed on the lower insulation layer 412 to fill a space between the plurality of first conductive lines 420. The plurality of first insulating patterns 422 may extend in the second direction D2. The upper faces of the plurality of first insulating patterns 422 may be disposed at the same level as the upper faces of the plurality of first conductive lines 420. The plurality of first conductive lines 420 may function as bit lines.

The plurality of first conductive lines 420 may include doped semiconductor material, metal, conductive metal nitride, conductive metal silicide, conductive metal oxide, or combinations thereof. For example, the plurality of first conductive lines 420 may be made up of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or a combination thereof. The plurality of first conductive lines 420 may include a single layer or multi-layers of the above-mentioned materials. In example embodiments, the plurality of first conductive lines 420 may include graphene, carbon nanotube or a combination thereof.

The channel layers 430 may be arranged in the form of a matrix in which they are disposed apart from each other in the first direction D1 and the second direction D2 on the plurality of first conductive lines 420. The channel layer 430 may have a first width along the first direction D1 and a first height along the second direction D2, and the first height may be greater than the first width. Here, the fourth direction D4 intersects the first direction D1 and the second direction D2, and may be, for example, a direction which is perpendicular to the upper face of the substrate 100. For example, the first height may be about 2 to 10 times the first width, but is not limited thereto. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

In example embodiments, the channel layer 430 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multi-layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 may have optimum channel performance when having the bandgap energy of about 2.0 eV to 4.0 eV. For example, the channel layer 430 may be polycrystalline or amorphous, but is not limited thereto. In some embodiments, the channel layer 430 may include graphene, carbon nanotube or a combination thereof.

The fourth gate electrode 440 may extend in the first direction D1 on both side walls of the channel layer 430. The fourth gate electrode 440 may include a first sub-gate electrode 440P1 that faces a first side wall of the channel layer 430, and a second sub-gate electrode 440P2 that faces a second side wall opposite to the first side wall of the channel layer 430. As the single channel layer 430 is disposed between the first sub-gate electrode 440P1 and the second sub-gate electrode 440P2, the semiconductor device may have a dual gate transistor structure. However, the technical idea of the present disclosure is not limited thereto, the second sub-gate electrode 440P2 may be omitted, and only the first sub-gate electrode 440P1 that faces the first side wall of the channel layer 430 may be formed to implement a single gate transistor structure. Materials included in the fourth gate electrode 440 may be the same as description of the third gate electrode 312.

The fourth gate insulating film 450 surrounds side walls of the channel layer 430, and may be interposed between the channel layer 430 and the fourth gate electrode 440. For example, as shown in FIG. 9, all side walls of the channel layer 430 may be surrounded by a fourth gate insulating film 450, and a part of the side walls of the fourth gate electrode 440 may be in contact with the fourth gate insulating film 450. In other embodiments, the fourth gate insulating film 450 extends in an extending direction of the fourth gate electrode 440 (that is, the first direction D1), and only two side walls among the side walls of the channel layer 430 that face the fourth gate electrode 440 may be in contact with the fourth gate insulating film 450. In example embodiments, the fourth gate insulating film 450 may be made of silicon oxide film, silicon oxynitride film, a high dielectric constant material having a higher dielectric constant than silicon oxide, or a combination thereof.

A plurality of second insulating patterns 432 may extend along the second direction D2 on the plurality of first insulating patterns 422. The channel layer 430 may be disposed between two adjacent second insulating patterns 432 among the plurality of second insulating patterns 432. Also, a first buried layer 434 and a second buried layer 436 may be disposed in a space between two adjacent channel layers 430, between two adjacent second insulating patterns 432. The first buried layer 434 may be disposed at the bottom part of the space between two adjacent channel layers 430. The second buried layer 436 may be formed to fill the rest of the space between two adjacent channel layers 430 on the first buried layer 434. The upper face of the second buried layer 436 may be disposed at the same level as the upper face of the channel layer 430, and the second buried layer 436 may cover the upper face of the fourth gate electrode 440. In contrast, the plurality of second insulating patterns 432 may be formed of a material layer continuous with the plurality of first insulating patterns 422, or the second buried layer 436 may be formed of a material layer continuous with the first buried layer 434.

Capacitor contacts 460 may be disposed on the channel layer 430. The capacitor contacts 460 are disposed to vertically overlap the channel layer 430, and may be arranged in the form of a matrix in which they are spaced apart from each other in the first direction D1 and the second direction D2. The capacitor contacts 460 may be made up of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or a combination thereof, but is not limited thereto. The upper insulating film 462 may surround the side walls of the capacitor contacts 460 on the plurality of second insulating patterns 432 and the second buried layer 436.

An etching stop film 470 may be disposed on the upper insulating layer 462. A second capacitor 480 may be disposed on the etching stop film 470. The second capacitor 480 may include a second lower electrode 482, a capacitor dielectric film 484, and a second upper electrode 486. The second lower electrode 482 penetrates the etching stop film 470 and may be electrically connected to the upper face of the capacitor contact 460. The second lower electrode 482 may be formed in a pillar type extending in the second direction D2, but is not limited thereto. In the example embodiments, the second lower electrode 482 is disposed to overlap perpendicularly to the capacitor contacts 460, and may be arranged in the form of a matrix in which they are spaced apart from each other in the first direction D1 and the second direction D2. In contrast, a landing pad (not shown) is further disposed between the capacitor contact 460 and the second lower electrode 482, and the second lower electrode 482 may be arranged in a hexagonal shape.

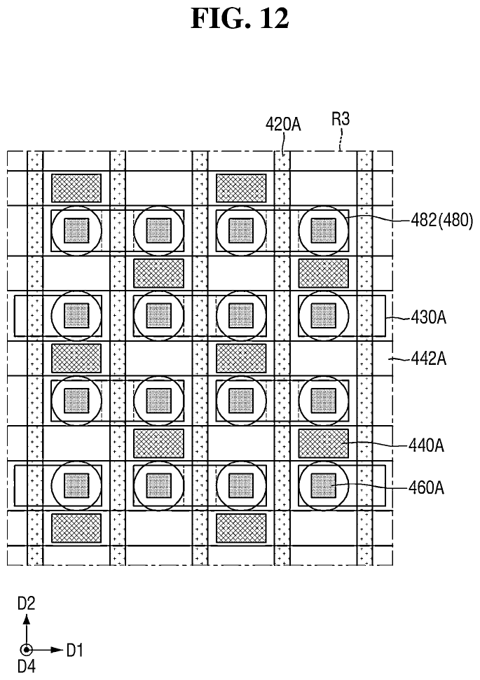

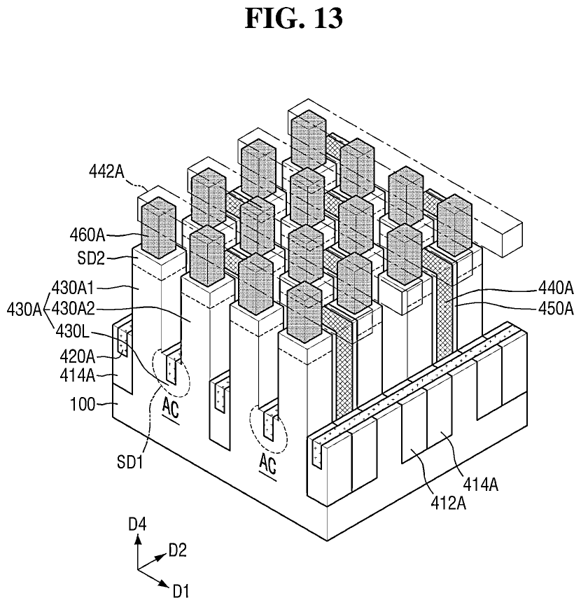

FIG. 12 is a layout diagram for explaining a semiconductor device according to some embodiments. FIG. 13 is a perspective view for explaining the semiconductor device according to some embodiments.

Referring to FIGS. 12 and 13, the semiconductor device according to some embodiments may include a substrate 100, a plurality of first conductive lines 420A, a channel structure 430A, a contact gate electrode 440A, a plurality of second conductive lines 442A, and a second capacitor 480. The semiconductor device according to some embodiments may be a memory device that includes a vertical channel transistor VCT.

A plurality of second active regions AC may be defined by the first element isolation pattern 412A and the second element isolation pattern 414A on the substrate 100. The channel structure 430A may be disposed in each second active region AC. The channel structure 430A may include a first active pillar 430A1 and a second active pillar 430A2 each extending in the vertical direction, and a connecting portion 430L connected to a bottom portion of the first active pillar 430A1 and a bottom portion of the second active pillar 430A2. A third source/drain region SD1 may be disposed inside the connecting portion 430L. A fourth source/drain region SD2 may be disposed above the first and second active pillars 430A1 and 430A2. The first active pillar 430A1 and the second active pillar 430A2 may each form an independent unit memory cell.

The plurality of first conductive lines 420A may extend in a direction intersecting each of the plurality of second active regions AC, and may extend, for example, in the second direction D2. One first conductive line 420A among the plurality of first conductive lines 420A may be disposed on the connecting portion 430L between the first active pillar 430A1 and the second active pillar 430A2. One first conductive line 420A may be disposed on the third source/drain region SD1. The other first conductive line 420A adjacent to the one first conductive line 420A may be disposed between the two channel structures 430A. One first conductive line 420A among the plurality of first conductive lines 420A may function as a common bit line included in two unit memory cells formed by the first active pillar 430A1 and the second active pillar 430A2 disposed on both sides of the one first conductive line 420A.

One contact gate electrode 440A may be disposed between the two channel structures 430A adjacent to each other in the second direction D2. For example, the contact gate electrode 440A may be disposed between the first active pillar 430A1 included in one channel structure 430A and the second active pillar 430A2 of the channel structure 430A adjacent thereto. One contact gate electrode 440 may be shared by the first active pillar 430A1 and the second active pillar 430A2 disposed on both side walls thereof. A fourth gate insulating film 450A may be disposed between the contact gate electrode 440A and the first active pillar 430A1, and between the contact gate electrode 440A and the second active pillar 430A2. The plurality of second conductive lines 442A may extend in the first direction D1 on the upper face of the contact gate electrode 440A. The plurality of second conductive lines 442A may function as word lines of the semiconductor device.

A capacitor contact 460A may be disposed on the channel structure 430A. The capacitor contact 460A may be disposed on the fourth source/drain region SD2, and the second capacitor 480 may be disposed on the capacitor contact 460A.

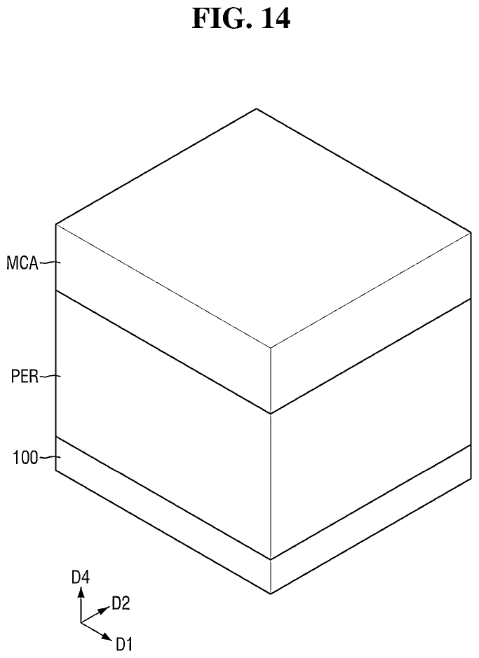

FIG. 14 is a diagram for explaining a semiconductor device according to some embodiments.

Referring to FIG. 14, the semiconductor device according to some embodiments may include a peri-gate structure PER and a memory cell structure MCA.

The peri-gate structure PER and the memory cell structure MCA may be disposed on the substrate 100. For example, the peri-gate structure PER may be disposed between the substrate 100 and the memory cell structure MCA.

For example, the semiconductor device described using FIGS. 1 to 4b may be disposed in the peri-gate structure PER. The semiconductor device described using FIGS. 5 to 13 may be disposed in the memory cell structure MCA. In other words, the capacitors 390 and 480 and bit lines included in the memory cell structure MCA may be disposed on the first gate electrode (120 of FIG. 1) and the second gate electrode (220 of FIG. 1) included in the peri-gate structure PER.

Unlike the shown example, the memory cell structure MCA may be disposed between the peri-gate structure PER and the substrate 100.

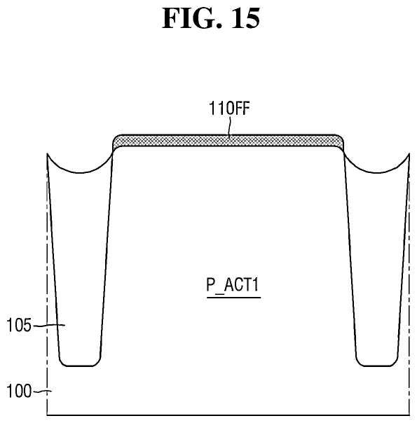

FIGS. 15 to 20 are intermediate operation diagrams for explaining a method of fabricating a semiconductor device according to some embodiments.

Referring to FIG. 15, a germanium feed film 110FF may be formed on the substrate 100. For example, the substrate 100 may be a silicon substrate.

The germanium feed film 110FF may be formed along the profile of the upper face of the substrate 100. The germanium feed film 110FF may include germanium. The germanium feed film 110FF may include at least one of a silicon germanium film or a germanium film.

The germanium feed film 110FF may be formed using, for example, a chemical vapor deposition (CVD) method or an atomic layer deposition (ALD) method. Although the germanium feed film 110FF is shown as not being formed on the first element isolation film 105, the embodiment is not limited thereto.

The germanium fraction of the germanium feed film 110FF may be 20% or more and 100% or less, but is not limited thereto.

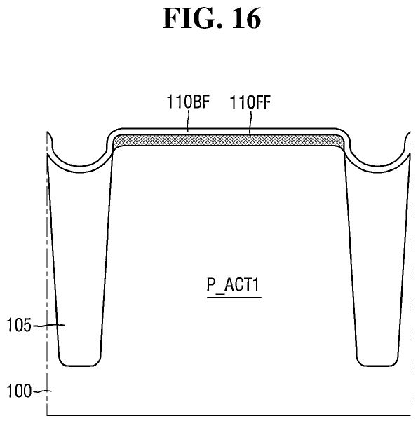

Referring to FIG. 16, a blocking film 110BF may be formed on the germanium feed film 110FF.

The blocking film 110BF may be formed along the profile of the germanium feed film 110FF. The blocking film 110BF may extend along the upper face of the first element isolation film 105.

The blocking film 110BF may limit and/or prevent germanium of the germanium feed film 110FF from diffusing in a direction away from the substrate 100 in a heat treatment process to be performed later.

As an example, the blocking film 110BF may include an insulating material. For example, the blocking film 110BF may include at least one of a silicon oxide film and a silicon nitride film. As another example, the blocking film 110BF may include a semiconductor material. For example, the blocking film 110BF may include polycrystal silicon. As another example, the blocking film 110BF may include a conductive material. For example, the blocking film 110BF may include, but is not limited to, titanium nitride (TiN).

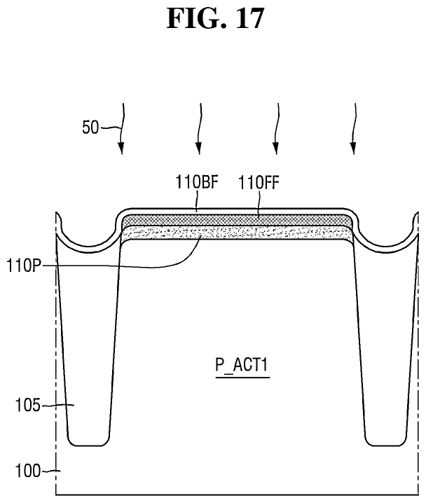

Referring to FIG. 17, germanium in the germanium feed film 110FF may diffuse into the substrate 100 through a first heat treatment process 50. Therefore, the pre-silicon germanium film 110P may be formed inside the substrate 100.

While the first heat treatment process 50 is performed, germanium in the germanium feed film 110FF may uniformly diffuse into the substrate 100 regardless of a plane index of the substrate 100. That is, germanium in the germanium feed film 110FF may be isotropically diffused into the substrate 100, while the first heat treatment process 50 is being performed. Therefore, the pre-silicon germanium film 110P may be conformally formed in the substrate 100.

Since the pre-silicon germanium film 110P is formed by germanium diffused from the germanium feed film 110FF, the germanium fraction of the pre-silicon germanium film 110P is smaller than the germanium fraction of the germanium feed film 110FF.

The blocking film 110BF is for limiting and/or preventing out-diffusion of germanium in the germanium feed film 110FF in a direction away from the substrate 100. That is, if the first heat treatment process 50 is performed at a heat treatment temperature at which out-diffusion of germanium does not become a problem, the first heat treatment process 50 may be performed in a state in which the blocking film 110BF is not formed.

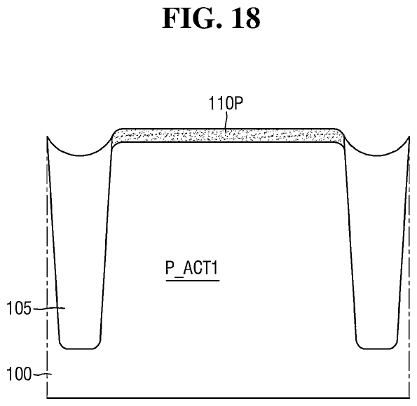

Referring to FIG. 18, the blocking film 110BF and the germanium feed film 110FF may be removed sequentially.

The germanium fraction of the germanium feed film 110FF is higher than the germanium fraction of the pre-silicon germanium film 110P. That is, due to a difference in germanium fraction, the pre-silicon germanium film 110P may have an etching selectivity with the germanium feed film 110FF. The germanium feed film 110FF may be removed, using a process with an etching selectivity according to the difference in germanium fraction.

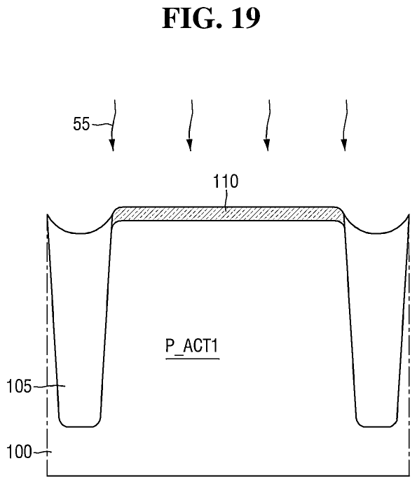

Referring to FIG. 19, the pre-silicon germanium film 110P may be recrystallized through a second heat treatment process 55.

Therefore, the silicon germanium film 110 may be formed. The silicon germanium film 110 may be formed on the substrate 100.

A first time during which the second heat treatment process 55 is performed is shorter than a second time during which the first heat treatment process 50 is performed. In order to limit and/or prevent diffusion of germanium of the pre-silicon germanium film 110P, the second heat treatment process 55 may be performed in a shorter time than the first heat treatment process 50.

Since the pre-silicon germanium film 110P formed using the diffusion process is used to form the silicon germanium film 110, the silicon germanium film 110 may be conformally formed regardless of the plane index of the substrate 100. The conformal silicon germanium film 110 may be formed regardless of the shape of the upper face of the substrate 100, by utilizing the method of fabricating a semiconductor device according to some embodiments of the present disclosure.

Also, when the silicon germanium film is formed on a substrate using an epitaxial growth process, a height difference occurs between a region in which an NMOS is formed and a region in which a PMOS is formed. Such a height difference increases the degree of difficulty of element integration. When the pre-silicon germanium film 110P is formed using a diffusion process, a height difference may not occur between the region in which the NMOS is formed and the region in which the PMOS is formed. That is, the degree of difficulty of the element integration may be reduced.

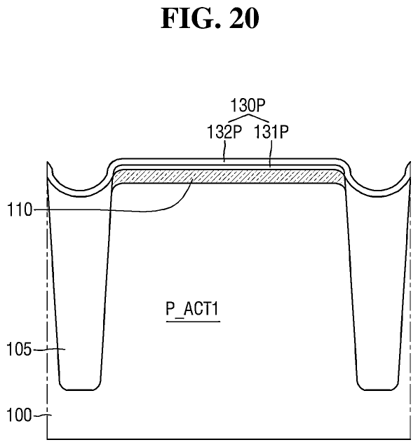

Referring to FIG. 20, a pre-gate insulating film 130P may be formed on the silicon germanium film 110. The pre-gate insulating film 130P may include a pre-interfacial film 131P and a pre-high dielectric constant insulating film 132P.

Subsequently, a gate electrode film may be formed on the pre-gate insulating film 130P. The first gate insulating film 130 and the first gate electrode 120 may be formed on the substrate 100, by patterning the gate electrode film and the pre-gate insulating film 130P.

In concluding the detailed description, those skilled in the art will appreciate that many variations changes and modifications may be made to example embodiments without substantially departing from the principles of inventive concepts. Therefore, the disclosed embodiments of are used in a generic and descriptive sense only and not for purposes of limitation.

What is claimed is:

1. A semiconductor device comprising:
a substrate including a first active region and a second active region;
an element isolation film on the substrate, the element isolation film exposing the first active region and the second active region;
a silicon germanium film on the first active region of the substrate;
a first gate insulating film on the silicon germanium film, the first gate insulating film contacting the silicon germanium film;
a first gate electrode on the first gate insulating film;
a source/drain region in the substrate and on both sides of the first gate electrode;
a second gate insulating film on the second active region of the substrate, the second gate insulating film contacting the substrate; and
a second gate electrode on the second gate insulating film, wherein
a height from a lowest portion of the element isolation film to an upper face of the substrate is different in the first active region compared to the second active region.

2. The semiconductor device of claim 1, wherein
the height from the lowest portion of the element isolation film to the upper face of the substrate in the first active region is smaller than the height from the lowest portion of the element isolation film to the upper face of the substrate in the second active region.

3. The semiconductor device of claim 1,
a lower face of the silicon germanium film faces the substrate,
an upper face of the silicon germanium film faces the first gate insulating film, and
a height from the lowest portion of the element isolation film to the upper face of the silicon germanium film in the first active region is equal to the height from the lowest portion of the element isolation film to the upper face of the substrate in the second active region.

4. The semiconductor device of claim 3,
wherein a germanium fraction of the silicon germanium film changes as the silicon germanium film goes away from the first gate insulating film.

5. The semiconductor device of claim 4,
wherein the germanium fraction of the silicon germanium film decreases as the silicon germanium film goes away from the first gate insulating film.

6. The semiconductor device of claim 1, wherein
an upper face of the element isolation film includes a contact point that is in contact with the silicon germanium film,
a lower face of the silicon germanium film faces the substrate and an upper face of the silicon germanium film faces the first gate insulating film, and
at least a part of the lower face of the silicon germanium film is located at a level below the contact point of the element isolation film and above the lowest portion of the element isolation film.

7. The semiconductor device of claim 1, wherein
a part of the source/drain region is inside the silicon germanium film.

8. The semiconductor device of claim 1, wherein
the first gate insulating film and the second gate insulating film each include an interfacial film and a high dielectric constant insulating film on the interfacial film.

9. The semiconductor device of claim 1, further comprising:
a capacitor on the substrate, wherein
the substrate includes a memory cell region and a peri-region,
the peri-region includes the first active region and the second active region, and
the capacitor is in the memory cell region.

10. The semiconductor device of claim 1, further comprising:
a bit line and a capacitor on the first gate electrode and the second gate electrode.

11. A semiconductor device comprising:
a substrate including a first active region and a second active region;
an element isolation film on the substrate, the element isolation film exposing the first active region and the second active region;
a silicon germanium film on the first active region of the substrate;
a first gate insulating film on the silicon germanium film;
a first gate electrode on the first gate insulating film;
a second gate insulating film on the second active region of the substrate; and
a second gate electrode on the second gate insulating film, wherein
a lower face of the silicon germanium film faces the substrate and an upper face of the silicon germanium film faces the first gate insulating film, and
a height from a lowest portion of the element isolation film to an upper face of the silicon germanium film in the first active region is equal to a height from a lowest portion of the element isolation film to an upper face of the substrate in the second active region.

12. The semiconductor device of claim 11, wherein
a germanium fraction of the silicon germanium film decreases as the silicon germanium film goes away from the first gate insulating film.

13. The semiconductor device of claim 11,
the first gate insulating film is in contact with the silicon germanium film, and
the second gate insulating film is in contact with the substrate.

14. The semiconductor device of claim 13,
the first active region includes a pMOS region, and
the second active region includes an nMOS region.

15. The semiconductor device of claim 11, wherein
the upper face of the substrate has a convex shape in the first active region, and
the silicon germanium film conformally covers the convex shape of the upper face of the substrate in the first active region.

16. The semiconductor device of claim 11, wherein
the first gate insulating film includes a silicon oxide film on the silicon germanium film and a high dielectric constant insulating film on the silicon oxide film, and
the silicon oxide film is in contact with the silicon germanium film.

17. A semiconductor device comprising:
a substrate including a first active region and a second active region;
an element isolation film on the substrate, the element isolation film exposing the first active region and the second active region;
a silicon germanium film on the first active region of the substrate, the silicon germanium film contacting the substrate;
a first gate insulating film on the silicon germanium film;
a first gate electrode on the first gate insulating film;
a second gate insulating film on the second active region of the substrate; and
a second gate electrode on the second gate insulating film, wherein
a lower face of the silicon germanium film faces the substrate and an upper face of the silicon germanium film faces the first gate insulating film,
a first height in the first active region is from a level of an upper face of the element isolation film to a level of the upper face of the silicon germanium film,
a second height in the second active region is from the level of the upper face of the element isolation film to a level of the upper face of the substrate, and
the first height equals the second height.

18. The semiconductor device of claim 17, wherein
a germanium fraction of the silicon germanium film decreases as the silicon germanium film goes away from the first gate insulating film.

19. The semiconductor device of claim 17, wherein
the upper face of the substrate has a convex shape in the first active region and the second active region, and
the silicon germanium film conformally covers the convex shape.

20. The semiconductor device of claim 17, wherein
the first gate insulating film is in contact with the silicon germanium film,
second gate insulating film is in contact with the substrate,
the first active region includes a pMOS region, and
the second active region includes an nMOS region.
